(19) United States
(12) Patent Application Publication
(10) Pub. No.: US 2014/0091371 A1
(43) Pub. Date: Apr. 3, 2014

(54) SEMICONDUCTOR DEVICE

(71) Applicant: SAMSUNG ELECTRONICS CO., LTD., Gyeonggi-do (KR)

(72) Inventor: Seung-hun Son, Seoul (KR)

(21) Appl. No.: 13/940,562

(22) Filed: Jul. 12, 2013

(30) Foreign Application Priority Data
Sep. 28, 2012 (KR) 10-2012-0109256

(51) Int. Cl. H01L 29/78

(52) U.S. Cl. CPC H01L 29/78
USPC 257/288

(57) ABSTRACT

A semiconductor device including: a substrate having a channel region and first and second recesses disposed on opposite sides of the channel region; a gate insulating layer disposed on the channel region; a gate structure disposed on the gate insulating layer; and a source region disposed in the first recess and a drain region disposed in the second recess, wherein the source region includes a first layer disposed on a surface of the first recess and a second layer disposed on the first layer and the drain region includes a third layer disposed on a surface of the second recess and a fourth layer disposed on the third layer; and a distance between the gate structure and the second layer of the source region is greater or less than a distance between the gate structure and the fourth layer of the drain region.

### CROSS-REFERENCE TO RELATED APPLICATION

This application claims priority under 35 U.S.C. §119 to Korean Patent Application No. 10-2012-0109256, filed on Sep. 28, 2012, in the Korean Intellectual Property Office, the disclosure of which is incorporated by reference herein in its entirety.

### BACKGROUND

1. Technical Field

The inventive concept relates to a semiconductor device, and more particularly, to a semiconductor device having improved gate-induced drain leakage (GIDL) characteristics and excellent reliability.

2. Discussion of the Related Art

As semiconductor devices become highly integrated, various characteristics thereof are considered in their design. The number of considered characteristics increases as semiconductor devices are used for logic circuits in memory devices. For example, in manufacturing embedded silicon germanium (eSiGe) semiconductor devices for use in memory devices, various characteristics including current leakage may be considered.

### SUMMARY

An exemplary embodiment of the inventive concept provides a semiconductor device having improved gate-induced drain leakage (GIDL) characteristics and excellent reliability.

According to an exemplary embodiment of the inventive concept, there is provided a semiconductor device including: a substrate having a channel region and first and second recesses disposed on opposite sides of the channel region; a gate insulating layer disposed on the channel region; a gate structure disposed on the gate insulating layer; and a source region disposed in the first recess and a drain region disposed in the second recess, wherein the source region comprises a first layer disposed on a surface of the first recess and a second layer disposed on the first layer and the drain region comprises a third layer disposed on a surface of the second recess and a fourth layer disposed on the third layer; and a distance between the gate structure and the second layer of the source region is greater or less than a distance between the gate structure and the fourth layer of the drain region.

An upper surface of each of the first and third layers is exposed, and a width of the third layer exposed in the drain region is greater than a width of the first layer exposed in the source region. A depth of the first recess of the source region may be greater than a depth of the second recess of the drain region. A maximum thickness of the first layer of the source region in a vertical direction may be substantially the same as a maximum thickness of the third layer of the drain region in the vertical direction.

The second recess of the drain region may have a box shape and the first recess of the source region may have a sigma shape. A depth of the second recess of the drain region may be less than a depth of the first recess of the source region.

The first layer and the second layer respectively may include germanium (Ge) and a germanium concentration of the second layer may be higher than a germanium concentration of the first layer.

The third layer and the fourth layer respectively may include Ge and a germanium concentration of the fourth layer may be higher than a germanium concentration of the third layer.

The semiconductor device may be a p-type metal-oxide-semiconductor (MOS) device.

The semiconductor device may further include first and second spacers disposed on lateral side walls of the gate structure. A thickness of a lower end of the second spacer in a lateral direction between the gate structure and the drain region may be greater than a thickness of a lower end of the first spacer in a lateral direction between the gate structure and the source region. At least one of the spacers and a corresponding recess side wall may be self-aligned.

An upper end of the first spacer between the gate structure and the source region may be at substantially the same level as an upper surface of the gate structure.

According to an exemplary embodiment of the inventive concept, there is provided a semiconductor device including: a substrate having a channel region and a source region and a drain region disposed on opposite sides of the channel region; a gate insulating layer disposed on the channel region; and a gate structure disposed on the gate insulating layer, wherein the source region and the drain region each comprise germanium (Ge) and each of the source region and the drain region comprises a first layer and a second layer whose germanium concentration is higher than a germanium concentration of the first layer; and a distance between the gate structure and the second layer of the drain region is greater than a distance between the gate structure and the second layer of the source region.

A lower surface of the first layer of the source region may be lower than a lower surface of the first layer of the drain region.

The semiconductor device may further include first and second spacers disposed on opposite side walls of the gate structure. A thickness of a lower end of the second spacer in a lateral direction between the gate structure and the drain region may be greater than a thickness of a lower end of the first spacer in a lateral direction between the gate structure and the source region.

The source region and the drain region may apply a compressive stress to the channel region.

According to an exemplary embodiment of the inventive concept, there is provided a semiconductor device including: a source region disposed on a first side of a gate structure; a drain region disposed on a second side of the gate structure; a first layer of the source region is exposed adjacent to the gate structure; and a second layer of the drain region is exposed adjacent to the gate structure, wherein more of the second layer is exposed than the first layer.

The source region may be disposed in a first recess in a substrate and the drain region may be disposed in a second recess in the substrate, wherein a depth of the first recess may be greater than a depth of the second recess.

The semiconductor device may further include a first spacer disposed on a first sidewall of the gate structure on the first side of the gate structure and a second spacer disposed on a second sidewall of the gate structure on the second side of the gate structure, and the second spacer may extend farther from the second sidewall than the first spacer extends from the first sidewall.

The first recess may have a sigma shape and the second recess may have a box shape.

### BRIEF DESCRIPTION OF THE DRAWINGS

The above and other features of the inventive concept will become more apparent by describing in detail exemplary embodiments thereof with reference to the accompanying drawings in which:

FIG. 1 is a cross-sectional view of a semiconductor device according to an exemplary embodiment of the present inventive concept;

FIG. 2 is a cross-sectional view of a semiconductor device according to an exemplary embodiment of the present inventive concept;

FIG. 3 is a view for more specifically explaining an exemplary embodiment of the inventive concept where an exposed width of a layer of a source region is smaller than an exposed width of a layer of a drain region;

FIGS. 4 to 6 are cross-sectional views of semiconductor devices according to exemplary embodiments of the present inventive concept;

FIGS. 7A to 7E are cross-sectional views illustrating a method of manufacturing the semiconductor device of FIG. 2 according to an exemplary embodiment of the present inventive concept;

FIGS. 8A to 8C are cross-sectional views illustrating a method of manufacturing the semiconductor device of FIG. 4 according to an exemplary embodiment of the present inventive concept;

FIGS. 9A to 9E are cross-sectional views illustrating a method of manufacturing the semiconductor device shown in FIG. 5 according to an exemplary embodiment of the present inventive concept;

FIG. 10 is a circuit diagram of a complementary metal oxide semiconductor (CMOS) inverter according to an exemplary embodiment of the present inventive concept.

FIG. 11 is a circuit diagram of a CMOS static random access memory (SRAM) device according to an exemplary embodiment of the present inventive concept.

FIG. 12 is a circuit diagram of a CMOS NAND circuit according to an exemplary embodiment of the present inventive concept;

FIG. 13 is a block diagram of an electronic system according to an exemplary embodiment of the present inventive concept;

FIG. 14 is a block diagram of an electronic system according to an exemplary embodiment of the present inventive concept; and

FIG. 15 is a view of an electronic subsystem according to an exemplary embodiment of the present inventive concept.

### DETAILED DESCRIPTION OF THE EMBODIMENTS

Hereinafter, exemplary embodiments of the present inventive concept will be described in detail with reference to the accompanying drawings. The inventive concept may, however, be embodied in many different forms and should not be construed as being limited to the embodiments set forth herein. The same reference numerals may denote like elements in the specification and drawings. As used herein, the singular forms “a,” “an” and “the” are intended to include the plural forms as well, unless the context clearly indicates otherwise.

FIG. 1 is a cross-sectional view of a semiconductor device 100 according to an exemplary embodiment of the present inventive concept. Referring to FIG. 1, a substrate 110 with a channel region 112 is provided. A gate dielectric 120 is disposed on the channel region 112, and a gate structure 130 is disposed on the gate dielectric 120.

The substrate 110 may be one on which a system large scale integration (system LSI), a logic circuit, an image sensor such as a complementary metal oxide semiconductor (CMOS) imaging sensor (CIS), a memory device such as a flash memory, a dynamic random access memory (DRAM), a static RAM (SRAM), an electrically erasable and programmable read only memory (EEPROM), a phase-change RAM (PRAM), a magnetic RAM (MRAM), or a resistive RAM (ReRAM), or a micro electromechanical system (MEMS) is disposed.

In particular, the substrate 110 may include any material suitable for a given purpose, and may be silicon (Si), silicon carbide (SiC), silicon germanium (SiGe), silicon germanium carbide (SiGeC), germanium (Ge) alloy, gallium arsenide (GaAs), indium arsenide (InAs), TnP, another III group-V group or II group-VI group compound semiconductor, or an organic semiconductor substrate. In addition, a p-type dopant such as phosphorous (P), arsenic (As), antimony (Sb) or an n-type dopant such as boron (B), indium (In), gallium (Ga) may be injected to the substrate 110 to form the channel region 112.

The gate dielectric 120 is disposed on the channel region 112. The gate dielectric 120 may be a silicon oxide or a metal oxide-based dielectric such as a hafnium oxide, etc. The gate dielectric 120 may be formed by chemical vapor deposition (CVD), atomic layer deposition (ALD), plasma oxidation, radical oxidation, thermal oxidation, and the like. However, the present inventive concept is not limited thereto.

The gate structure 130 is disposed on the gate dielectric 120. The gate structure 130 may include conductive materials. The conductive materials may include conductive polysilicon, metals, metallic silicide, conductive metallic nitrides, conductive metallic oxides, or their alloys. For example, the conductive materials may include dopant doped polysilicon, tungsten (W), tungsten nitrides, tungsten silicide, aluminum (Al), aluminum nitrides, tantalum (Ta), tantalum nitrides, tantalum silicide, titanium (Ti), titanium nitrides, cobalt silicide, molybdenum (Mo), ruthenium (Ru), nickel (Ni), nickel silicide, or their combinations. In exemplary embodiments of the inventive concept, the conductive materials may be formed by using a CVD, ALD or sputtering process.

The gate structure 130 may further include a capping layer on the conductive material. The capping layer may include silicon nitrides, for example.

A source region 140A and a drain region 140B are respectively arranged on either side of the gate structure 130. Each of the source region 140A and the drain region 140B may include a first layer 140A_1 and 140B_1, and a second layer 140A_2 and 140B_2. The second layers 140A_2 and 140B_2 may be arranged on the first layers 140A_1 and 140B_{—}1.

The first layers 140A_1 and 140B_1 and the second layers 140A_2 and 140B_2 may include hetero elements such as Ge. In particular, the hetero element such as Ge may be included as an element that forms a part of a crystal lattice of a single crystalline substrate. The first layers 140A_1 and 140B_1 may include the hetero element such as Ge by about 5 atomic % (at %) to about 25 at % for example. In addition, the second layers 140A_2 and 140B_2 may include the hetero element such as Ge by about 25 at % to about 50 at % for example. If the hetero element such as Ge is added in this way, compressive stress or tensile stress may be applied to the channel region 112 depending on the kind of the hetero element. By applying compressive stress or tensile stress to the channel region 112 in this way, it may be possible to control the carrier mobility in the channel region 112.

The first layers 140A_1 and 140B_1 may play a role as a buffer layer that alleviates a change in the lattice constant between the substrate 110 and the constituent materials of each of the second layers 140A_2 and 140B_2 to prevent defects such as dislocation due to an abrupt change in the lattice constant between them.

In addition, a dopant such as B may be doped on each of the first layers 140A_1 and 140B_1 and the second layers 140A_2 and 140B_2. In particular, the concentration of B doped in the second layers 140A_2 and 140B_2 may be greater than that doped in the first layers 140A_1 and 140B_{—}1.

As illustrated in FIG. 1, part of the first layers 140A_1 and 140B_1 may be exposed between the gate structure 130 and the second layers 140A_2 and 140B_2. In this case, for the exposed part of the first layers 140A_1 and 140B_1, the exposed width W2 of the first layer 140B_1 of the drain region 140B may be greater than the exposed width W1 of the first layer 140A_1 of the source region 140A. In other words, the distance between the gate structure 130 and the second layer 140B_2 of the drain region 140B may be greater than that between the gate structure 130 and the second layer 140A_2 of the source region 140A.

Alternatively, the exposed width W2 of the first layer 140B_1 of the drain region 140B may be smaller than the exposed width W1 of the first layer 140A_1 of the source region 140A. In other words, the distance between the gate structure 130 and the second layer 140B_2 of the drain region 140B may be smaller than that between the gate structure 130 and the second layer 140A_2 of the source region 140A.

By making the distance between the gate structure 130 and the second layer 140B_2 of the drain region 140E greater than that between the gate structure 130 and the second layer 140A_2 of the source region 140A, properties related to gate-induced drain leakage (GIDL) may be improved.

The exemplary embodiments of the inventive concept to be discussed below focus mainly on the embodiment where the exposed width W2 of the first layer 140B_1 of the drain region 140B is greater than the exposed width W1 of the first layer 140A_1 of the source region 140A. The embodiment where the exposed width W2 of the first layer 140B_1 of the drain region 140B is smaller than the exposed width W1 of the first layer 140A_1 of the source region 140A can be fully appreciated by those of ordinary skill in the art by referring to the following descriptions.

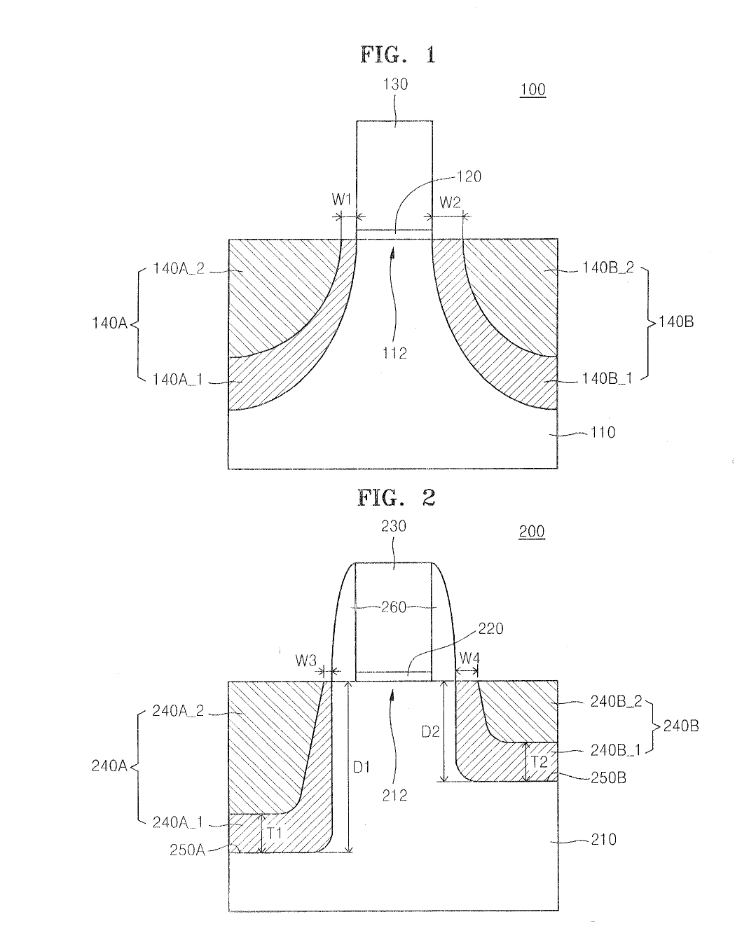

FIG. 2 is a cross-sectional view of a semiconductor device 200 according to an exemplary embodiment of the present inventive concept. Referring to FIG. 2, a substrate 210 with a channel region 212 is provided. A gate dielectric 220 is disposed on the channel region 212, and a gate structure 230 is disposed on the gate dielectric 220. In addition, a source region 240A and a drain region 240B are respectively on either side of the gate structure 230. In particular, spacers 260 may be disposed on sidewalls of the gate structure 230 facing the source region 240A and the drain region 240B. The widths of the bottoms of the spacers 260 at both sides may be substantially the same each other.

The source region 240A and the drain region 240B may be in recesses 250A and 250B, respectively. Optionally, the source region 240A and the drain region 240B may be formed by epitaxial growth in the recesses 250A and 250B, respectively.

Each of the source region 240A and the drain region 240B includes a first layer 240A_1 and 240B_1 and a second layer 240A_2 and 240B_2. The first layers 240A_1 and 240B_1 may be formed to cover the bottom surfaces and side surface of the recesses 250A and 250B. The growth rate of the first layers 240A_1 and 240B_1 is faster in the vertical direction than the horizontal direction if they are formed by epitaxial growth. As a result, as shown in the first layer 240A_1 of the source region 240A, the vertical thickness is greater than the horizontal thickness. In particular, the horizontal thickness of the first layer 240A_1 may become thinner from the bottom to the top.

The first layer 240A_1 of the source region 240A and the first layer 240B_1 of the drain region 240B may be simultaneously formed in the same process. In this case, the height T1 of the first layer 240A_1 of the source region 240A and the height T2 of the first layer 240B_1 of the drain region 240B may be substantially the same.

In addition, the depth D1 of the recess 250A of the source region 240A may be greater than the depth D2 of the recess 250B of the drain region 240B. In this case, the exposed width W4 of the first layer 240B_1 of the drain region 240B is substantially the same as the width of the first layer 240A_1 of the source region 240A at a height corresponding to the depth D2 of the drain region 240B from the bottom of the recess 250A. Since the width of the first layer 240A_1 of the source region 240A becomes smaller from this point toward the upper part of the recess 250A, the exposed width W3 of the first layer 240A_1 of the source region 240A becomes smaller than the exposed width W4 of the first layer 240B_1 of the drain region 240B.

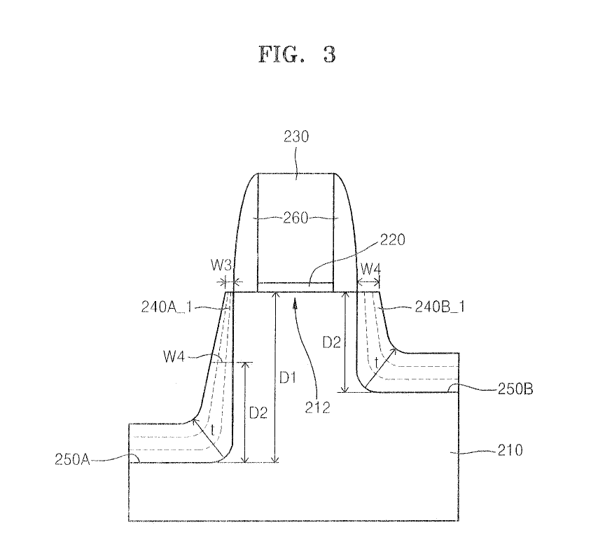

FIG. 3 is a view for more specifically explaining an exemplary embodiment where the width W3 is smaller than the width W4. Referring to FIG. 3, the first layers 240A_1 and 240B_1 are respectively formed in the recess 250A of the source region 240A and the recess 250 of the drain region 240B. The first layers 240A_1 and 240B_1 may be formed by epitaxial growth. The dotted lines of FIG. 3 represent the profiles of epitaxial growth at specific periods and the first layers 240A_1 and 240B_1 grow in arrow directions that are represented by t.

As illustrated in FIG. 3, the epitaxial growth is relatively slower in the upper part of the recesses than in the lower part of the recesses. If the depths of the two recesses 250A and 250B are different from each other, it may be considered that the recesses have the same epitaxial growth profiles at the same depth. If the depth D1 of the recess 250A of the source region 240A is deeper than the depth D2 of the recess 250B of the drain region 240B as represented in FIG. 3, the width W4 of the exposed upper surface of the recess 250B of the drain region 240B may be the same as the width W4 at a point that is the depth D2 from the bottom of the recess 250A of the source region 240A. In addition, since the epitaxial growth rate gets slower as the distance from the bottom of the recess is farther away, the width at the exposed upper surface of the recess 250A may be the width W3 that is smaller than width W4 of the recess 250A.

Referring back to FIG. 2, the second layers 240A_2 and 240B_2 are formed in the remaining spaces of the recesses 250A and 250B. The second layers 240A and 240B_2 may also be formed by epitaxial growth. As described above with reference to FIG. 1, the hetero element such as Ge may be included in the first layers 240A_1 and 240B_1 and the second layers 240A_2 and 240B_2, and the content of such a hetero element is higher in the second layers 240A_2 and 240B_2 than in the first layers 240A_1 and 240B_{—}1.

By doing this, the distance between the gate structure 230 and the second layer 240B_2 of the drain region 240B may be made greater than that between the gate structure 230 and the second layer 240A_2 of the source region 240A.

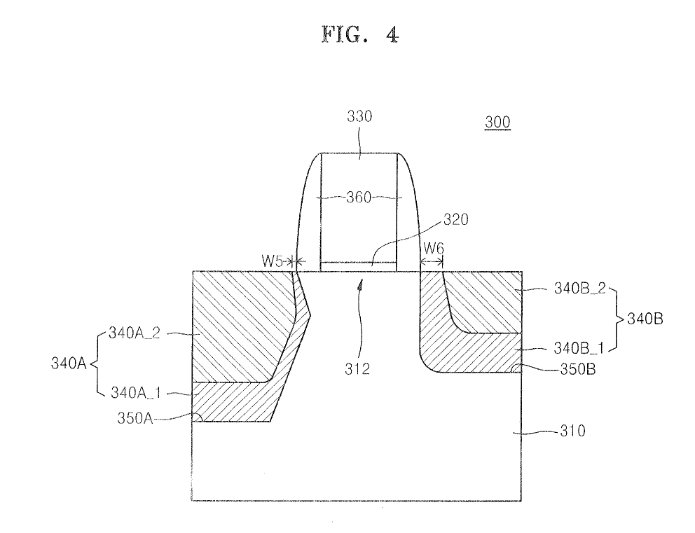

FIG. 4 is a cross-sectional view of a semiconductor device 300 according to an exemplary embodiment of the present inventive concept. Referring to FIG. 4, a drain region 340B may have a box-type recess 350B and a source region 340A may have a sigma-type recess 350A. The drain region 340B and the source region 340A may be on opposite sides of a channel region 312.

In this case, the box type may mean a recess in which a sidewall is extended perpendicularly to the upper surface regardless of the crystal direction of a substrate 310 and the bottom is horizontally extended. Further, the sidewall may not accurately meet the bottom at 90° and they may meet by making a curve as represented in FIG. 4.

In addition, the sigma type may mean a recess in which surfaces that form the sidewall and the bottom are determined in accordance with the crystalline orientation of the substrate 310. In other words, if the substrate 310 is wet etched, the recess 350A may be formed to have a polygonal sectional profile including a plurality of surfaces having {111} crystalline orientation as represented in FIG. 4.

For example, the box type recess may be formed by dry etching and the sigma-type recess may be formed by wet etching. Optionally, the sigma-type recess may be formed by further performing wet etching following the dry etching.

In this way, the recess 350A of the source region 340A and the recess 350B of the drain region 340B may be formed as different types. Although FIG. 4 illustrates that the source region 340A has the sigma-type recess 350A and the drain region 340B has the box-type recess 350B, the source region 340A may have the box-type recess 350B and the drain region 340B may have the sigma-type recess 350A.

In particular, the recesses 350A and 350B may be formed so that the depth of the recess 350A of the source region 340A is greater than that of the recess 350B of the drain region 340B. The exposed width W6 of the first layer 340B_1 of the drain region 340B may be made to be greater than the exposed width W5 of the first layer 340A_1 of the source region 340A as described in FIG. 2.

Alternatively, the depth of the recess 350A of the source region 340A may be made to be substantially the same as that of the recess 350B of the drain region 340B. In general, the lateral epitaxial growth rate in a box-type recess is somewhat faster than that in a sigma-type recess. Thus, even if the depth of the recess 350A of the source region 340A is the same as that of the recess 350B of the drain region 340B, the exposed width W6 of the first layer 340B_1 of the drain region 340B grown in the box-type recess is greater than the exposed width W5 of the first layer 340A_1 of the source region 340A grown in the sigma-type recess.

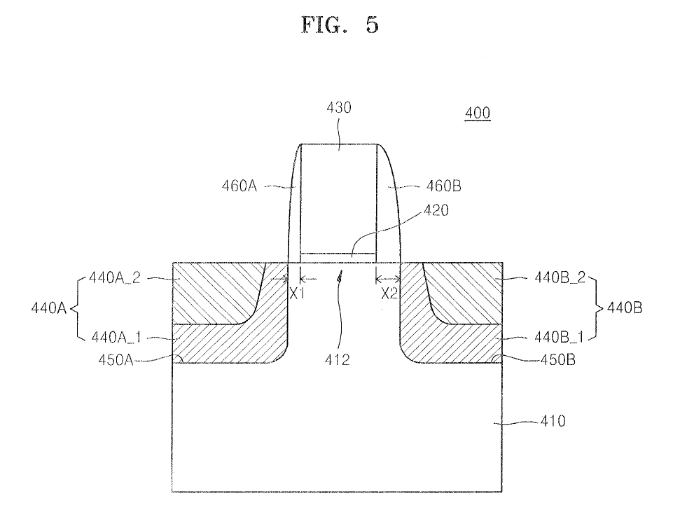

FIG. 5 is a cross-sectional view illustrating a semiconductor device 400 according to an exemplary embodiment of the inventive concept. Referring to FIG. 5, spacers 460A and 460B are provided on opposite sidewalls of a gate structure 430. The spacers 460A and 460B may have a single-layer structure or a multilayer structure in which multiple layers are stacked. The spacer 460A of the side of a source region 440A may not have the same structure as the spacer 460B of the side of a drain region 440B, and thus the spacer 460A and the spacer 460B may have different structures than each other. For example, the spacer 460A on the side of the source region 440A may be formed in a single layer, and the spacer 460B of the side of the drain region 440B may have a multilayer structure. The drain region 440B and the source region 440A may be on opposite sides of a channel region 412.

In particular, a thickness of the spacer 460B of the side of the drain region 440B may be thicker than that of the spacer 460A of the side of the source region 440A. More specifically, a lateral thickness X2 of a lower end of the spacer 460B of the side of the drain region 440B may be thicker than a lateral thickness X1 of a lower end of the spacer 460A of the side of the source region 440A.

As illustrated in FIG. 5, at least one of the spacers 460A and 460B may be self-aligned with sidewalls of recesses 450A and 450B.

The recess 450A of the side of the source region 440A and the recess 450B of the side of the drain region 440B may have substantially the same depth. Since the recesses 450A and 450B have substantially the same depth, first layers 440A_1 and 440B_1 formed on inner surfaces of the recesses 450A and 450B have almost the same dimensions. As a result, the first layer 440A_1 exposed at the side of the source region 440A may have substantially the same thickness as the first layer 440B_1 exposed at the side of the drain region 440B. In this case, a distance between the gate structure 430 and a second layer 440B_2 of the drain region 440B is greater than that between the gate structure 430 and a second layer 440A_2 of the source region 440A by as much as X2-X1.

Even though the recess 450A of the side of the source region 440A and the recess 450B of the side of the drain region 440B have substantially the same depth, the thicknesses of the first layers 450A_1 and 450B_1 may be affected when the thickness of the spacer 460B of the side of the drain region 440B is significantly greater than that of the spacer 460A of the side of the source region 440A. In other words, when the spacer 460B of the side of the drain region 440B is significantly thicker than that of the spacer 460A of the side of the source region 440A, a horizontal width of the recess 450B of the side of the drain region 440B may be significantly smaller than that of the recess 450A of the side of the source region 440A.

When a plurality of the gate structures 430 are formed at constant intervals to form a plurality of the semiconductor devices 400 at constant intervals on a substrate 410, the lateral widths of the recesses 450A and 450B that may be formed between the gate structures 430 may depend on the lateral thicknesses of the lower ends of the spacers 460A and 460B. Further, when a ratio of an area of the recess with respect to an area of the substrate decreases as the width of the recess decreases, an epitaxial growth rate in the recess may increase. Since a ratio of an area of the recess 450B of the drain region 440B with respect to the area of the substrate 410 is smaller than a ratio of an area of the recess 450A of the source region 440A with respect to the area of the substrate 410, a growth rate of the first layer 440B_1 in the recess 450B of the drain region 440B may be faster than that of the first layer 440A_1 in the recess 450A of the source region 440A. As a result, an exposed width of the first layer 440B_1 at the drain region 440B may be greater than that of the first layer 440A_1 at the source region 440A. In this case, since the thickness of the spacer 460B and the exposed width of the first layer 440B_1 at the drain region 440B are greater than those at the source region 440A, the distance between the gate structure 430 and the second layer 440B_2 at the drain region 440B is greater than that between the gate structure 430 and the second layer 440A_2 at the source region 440A.

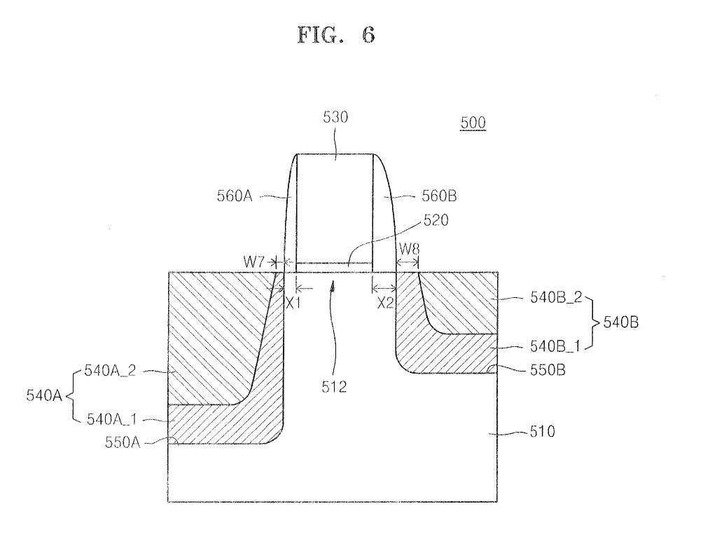

FIG. 6 is a cross-sectional view illustrating a semiconductor device 500 according to an exemplary embodiment of the inventive concept. Referring to FIG. 6, spacers 560A and 560B are provided on opposite sidewalls of a gate structure 530. This semiconductor device is the same as that of FIG. 5 except that a depth of a recess 550A at a source region 540A is greater than that of a recess 550E at a drain region 540B. The drain region 540B and the source region 540A may be on opposite sides of a channel region 512. A gate dielectric 520 may be disposed between a substrate 510 and the gate structure 530.

As described above with reference to FIG. 2, even though the thicknesses of the spacers 560A and 560B are substantially the same, an exposed width of a first layer is greater at a recess having a smaller depth (550B in FIG. 6) than at a recess having a greater depth (550A in FIG. 6).

As illustrated in FIG. 6, a lateral thickness X2 of a lower end of the spacer 560B of the drain region 540B is greater than a lateral thickness X1 of a lower end of the spacer 560A of the source region 540A. Moreover, as described above, an exposed width W8 of a first layer 540B_1 at the drain region 540B is greater than an exposed width W7 of a first layer 540A_1 at the source region 540A. As a result, a distance W8+X2 between the gate structure 530 and a second layer 540B_2 of the drain region 540B is significantly greater than a distance W7+X1 between the gate structure 530 and a second layer 540A_2 of the source region 540A.

In addition, as described above, if the lateral thickness X2 of the lower end of the spacer 560B of the drain region 540B is significantly greater than the lateral thickness X1 of the lower end of the spacer 560A of the source region 540A, a horizontal width of the recess 550B of the side of the drain region 540B may be significantly smaller than that of the recess 550A of the side of the source region 540A. As described above, if a ratio of an area of the recess with respect to an area of the substrate decreases as the width of the recess decreases, an epitaxial growth rate in the recess may increase. As a result, this horizontal width difference between the spacers 560A and 560B may additionally help the exposed width of the first layer 540B_1 at the drain region 540B be greater than that of the first layer 540A_1 at the source region 540A.

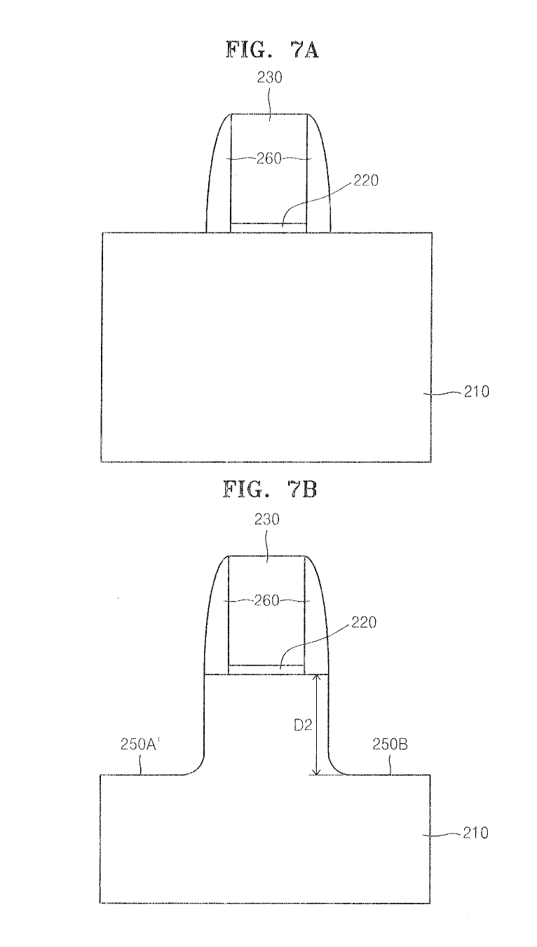

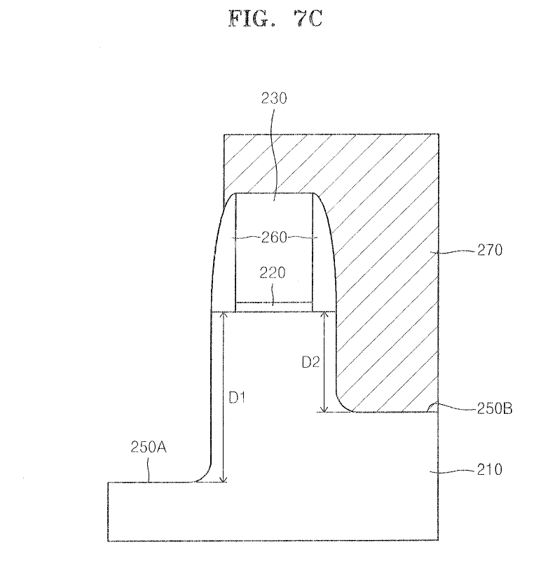

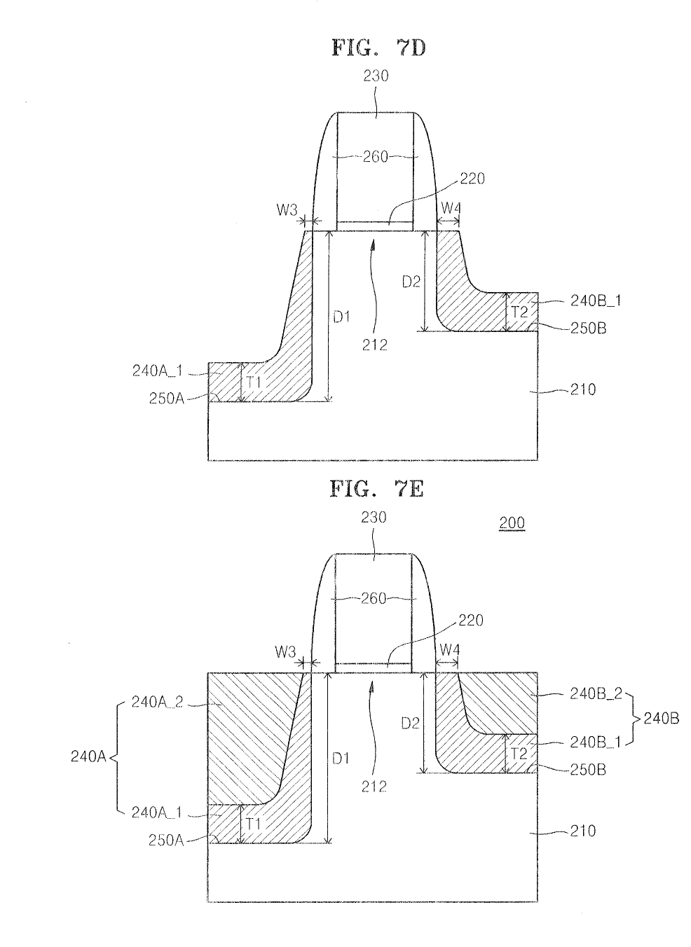

FIGS. 7A to 7E are cross-sectional views illustrating a method of manufacturing the semiconductor device 200 of FIG. 2 according to an exemplary embodiment of the inventive concept.

Referring to FIG. 7A, a gate insulating material layer and a gate structure material layer are formed on the substrate 210, and a mask pattern is formed on the gate structure material layer. Then, by using the mask pattern as an etching mask, the gate insulating material layer and the gate structure material layer are etched and patterned to thereby form the gate dielectric 220 and the gate structure 230. Since the substrate 210, the gate dielectric 220, and the gate structure 230 have been described above in detail, detailed descriptions thereof are not provided here.

Thereafter, a remaining etching mask, if any, is removed, and then a spacer material layer is formed over the substrate 210 and the gate structure 230 and is anisotropically etched to thereby form the spacer 260.

Referring to FIG. 7B, a part of the substrate 210 is anisotropically etched using the gate structure 230 and the spacer 260 as an etching mask to thereby form the recess 250A′ of the source region and the recess 250B of the drain region having a depth of D2. To anisotropically etch the substrate 210, dry etching such as reactive ion etching (RIE), inductively coupled plasma (ICP) etching, electron cyclotron resonance (ECR) etching, magnetron plasma etching, capacitively coupled plasma etching, dual-frequency plasma etching, and helicon wave plasma etching may be used. Since the gate structure 230 and the spacer 260 are used as an etching mask, sidewalls of the spacer 260 and the recesses 250A′ and 250 may be self-aligned.

For example, in the case where the substrate 210 is etched using the ICP etching, the etching may be performed by flowing about 7.5 sccm of CHF₃ as an etching gas and about 100 sccm of He as a carrier gas. The reaction pressure may be about 5.5 Pa and the temperature of a lower electrode may be about 70° C. The RF (13.56 MHz) power applied to a coil electrode may be about 475 W and the power applied to a lower electrode (bias side) may be about 300 W. The etching time may be about 10 seconds. A chlorine-based gas such as Cl₂, BCl₃, SiCl₄, or CCl₄, a fluorine-based gas such as CF₄, SF₆, or NF₃, or O₂ may be appropriately used as the etching gas instead of the fluoric gas CHF₃.

Referring to FIG. 7C, an etching mask 270 is formed to cover the gate structure 230 and the recess 250B of the drain region. The etching mask 270 may be formed of, for example, a photoresist material. Then, by performing etching in the same manner as described with reference to FIG. 7B, the recess 250A of the source region having a depth of D1 is finally obtained. Thereafter, the etching mask 270 may be removed.

Referring to FIG. 7D, the first layers 240A_1 and 240B_1 are respectively formed in the recess 250A of the source region and the recess 250B of the drain region. The first layers 240A_1 and 240B_1 may be formed to partially fill the recesses 250A and 250B. In other words, the first layers 240A_1 and 240B_1 may be formed from the bottoms and sidewalls of the recesses 250A and 250B to fill only parts of the inner spaces of the recesses. The first layers 240A_1 and 240B_1 may be formed to have a composition that is different from that of the substrate 210. For example, the first layers 240A_1 and 240B_1 may include a hetero element such as germanium, for example, in an amount of about 5 atom % to about 25 atom %.

The first layers 240A_1 and 240B_1 may act as buffers to prevent a defect such as dislocation caused by a rapid change in a lattice size between the substrate 210 composed of Si and a SiGe layer that is to be formed in the remaining spaces of the recesses 250A and 250B at a following process and has a relatively large amount of hetero elements.

In exemplary embodiments of the inventive concept, a selective epitaxial growth (SEG) process may be used to form the first layers 240A_1 and 240B_1. The first layers 240A_1 and 240B_1 may be selectively formed in the recesses 250A and 250B where silicon (Si) is exposed.

A process gas for forming the first layers 240A_1 and 240B_1 may include a Si source gas and a Ge source gas. For example, at least one of silane, alkyl silane, silane halide, and amino silane may be used as the Si source gas, and, for example, the Si source gas may be SiH₄, Si(CH₃)₄, Si(C₂H₅)₄, Si(N(CH₃)₂)₄, and SiH₂Cl₂. For example, at least one of germane, alkyl germane, and amino germane may be used as the Ge source gas, and, for example, the Ge source gas may be GeH₄, Ge(CH₃)₄, Ge(C₂H₅)₄, and Ge(N(CH₃)₂)₄.

In exemplary embodiments of the inventive concept, the process gas for forming the first layers 240A_1 and 240B_1 may further include a hydrogen gas and an inert gas such as nitrogen, argon, and helium. In exemplary embodiments of the inventive concept, the process gas for forming the first layers 240A_1 and 240B_1 may further include a control gas for controlling selectivity of SiGe growth and a growth rate of SiGe. The control gas may be HCl.

In exemplary embodiments of the inventive concept, the first layers 240A_1 and 240B_1 may be doped with impurities. For example, to obtain the first layers 240A_1 and 240B_1 formed in impurity-doped SiGe layers, impurity ions may be in situ doped while SiGe layers are grown by the SEG process in the recesses 250A and 250B. Boron (B) ions may be used as the impurity ions. When the process gas for forming the first layers 240A_1 and 240B_1 is supplied onto the substrate 210 to in situ dope the impurity ions, the B source gas may be simultaneously supplied onto the substrate 210 together with the process gas. B₂H₆ gas may be used as the B source gas.

Alternatively, to obtain the first layers 240A_1 and 240B_1 formed in impurity-doped SiGe layers, after growing the SiGe layers in the recesses 250A and 250B using the SEG process, an ion injection process for doping a dopant and an annealing process for activating the injected dopant may be performed.

While the first layers 240A_1 and 240B_1 are formed, a process pressure may be maintained at a certain level that is greater than about 0 Torr and is equal to or smaller than about 200 Torr, and a process temperature may range from about 500° C. to about 700° C.

Referring to FIG. 7E, the second layers 240A_2 and 240B_2 may be formed in the remaining inner spaces of the recesses 250A and 250B. The hetero element content in the second layers 240A_2 and 240B_2 may be higher than that in the first layers 240A_1 and 240B_1. For example, the second layers 240A_2 and 240B_2 may be SiGe layers of which a Ge content is higher than that in the first layers 240A_1 and 240_B. In exemplary embodiments of the inventive concept, the second layers 240A_2 and 240B_2 may be formed in SiGe layers of which the Ge content is about 25 atom % to about 50 atom %.

To form the second layers 240A_2 and 240B_2, a process that is similar to the process for forming the first layers 240A_1 and 240B_1 as described above with reference to FIG. 7D may be used. Therefore, to avoid repeated description, a detailed description of the process for forming the second layers 240A_2 and 240B_2 is omitted. Here, while the second layers 240A_2 and 240B_2 are formed, a process pressure may be maintained at a relatively low level that is greater than about 0 Torr and is equal to or smaller than about 5 Torr. Since the second layers 240A_2 and 240B_2 are formed under a relatively low pressure of about 5 Torr or less, the probability of a defect such as dislocation in the second layers 240A_2 and 240B_2 is reduced. As a result, it is possible to form the second layers 240A_2 and 240B_2 formed of SiGe layer materials having no defect or almost no defect.

When the second layers 240A_2 and 240B_2 are formed in B-doped SiGe layers by doping B ions in situ while SiGe is grown, a reaction for decomposing the B source, B₂H₆, to BH₃, and a subsequent reaction, e.g., decomposition from BH₃ to B ions are promoted by maintaining the process pressure at a relatively low level of about 5 Torr or less. Therefore, a desired B-doping concentration in the second layers 240A_2 and 240B_2 may be adjusted to have a relatively high Ge content.

For example, in the manner as described above, the semiconductor device 200 as illustrated in FIG. 2 may be manufactured.

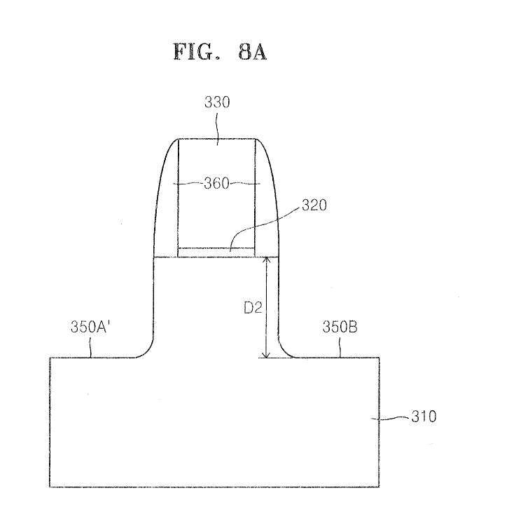

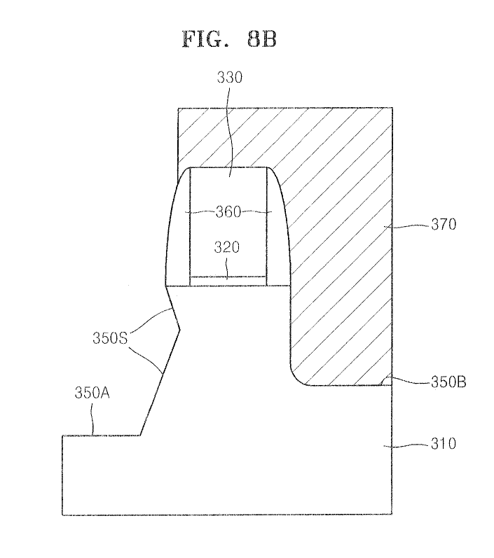

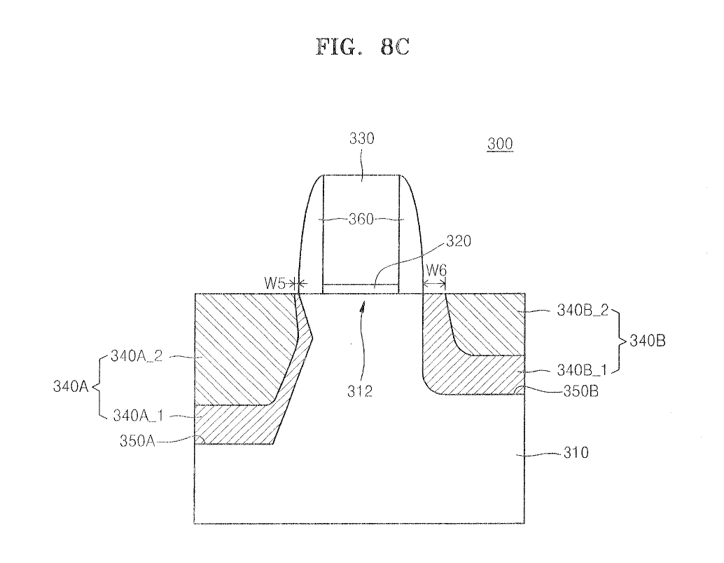

FIGS. 8A to 8C are cross-sectional views illustrating a method of manufacturing the semiconductor device 300 of FIG. 4 according to an exemplary embodiment of the present inventive concept.

Referring to FIG. 8A, the gate dielectric 320 and the gate structure 330 are formed on the substrate 310 and spacers 360 are formed on both sides of the gate structure 330, and then, this obtained structure is anisotropically etched to a certain depth using the gate structure 330 and the spacers 360 as an etching mask. As a result, a pair of recesses 350A′ and 350B is formed on both sides of the gate structure 330. Since FIG. 8A is substantially the same as FIG. 7A, a detailed description is omitted.

Referring to FIG. 8B, an etching mask 370 is formed to cover the gate structure 330 and the recess 350B of the drain region. The etching mask 370 may be formed using, for example, a photoresist material. Then, the recess 350A′ of the source region is isotropically etched using an etchant. The isotropic etching may be, for example, wet etching. Any etchant capable of selectively etching an inner wall of the recess 350A′ may be used as the etchant. For example, the etchant may be an NH₄OH solution, a trimethyl ammonium hydroxide (TMAH), an HF solution, an NH₄F solution, or a mixture thereof. However, the etchant is not limited thereto.

When the inner wall of the recess 350A′ is selectively etched using the etchant, a crystal surface selected from among crystal surfaces of the substrate 310 may be used as an etch stop surface. For example, a {111} crystal surface of the substrate 310 may be used as the etch stop surface. Under this etching condition, an etching rate in the {111} crystal surface of the substrate 310 may be much slower than that in other crystal surfaces. When the substrate 310 is etched using the etchant, the etching is performed until the {111} crystal surface 350S is exposed in the inner wall of the recess 350A′ so that the recess 350A having a sigma-type cross section may be obtained. Thereafter, the etching mask 370 may be removed.

Referring to FIG. 8C, the first layers 340A_1 and 340B_1 and the second layers 340A_2 and 340B_2 are sequentially formed in the recesses 350A and 350B. The method of forming the first layers 340A_1 and 340B_1 and the second layers 340A_2 and 340B_2 in the recesses 350A and 350B has been described in detail with reference to FIGS. 7D and 7E. Thus, a redundant description is omitted here.

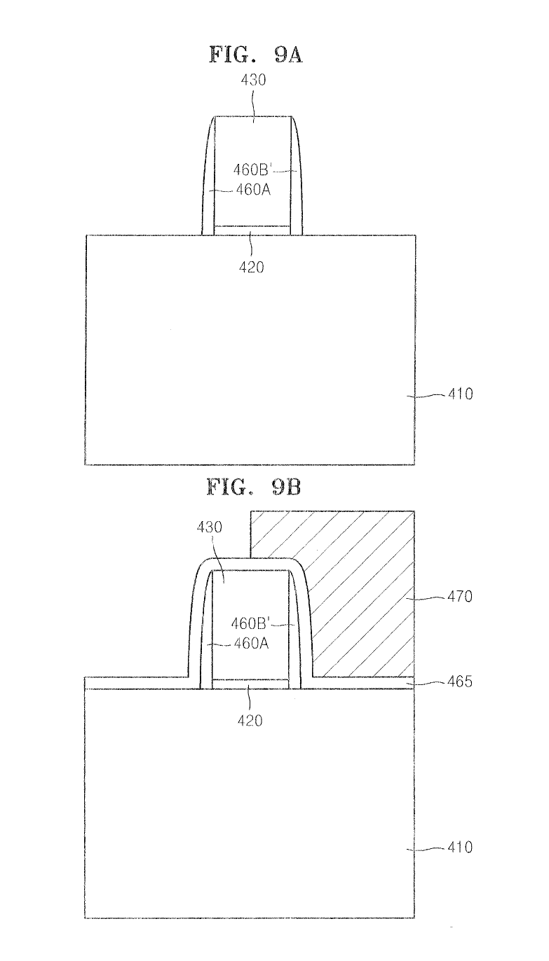

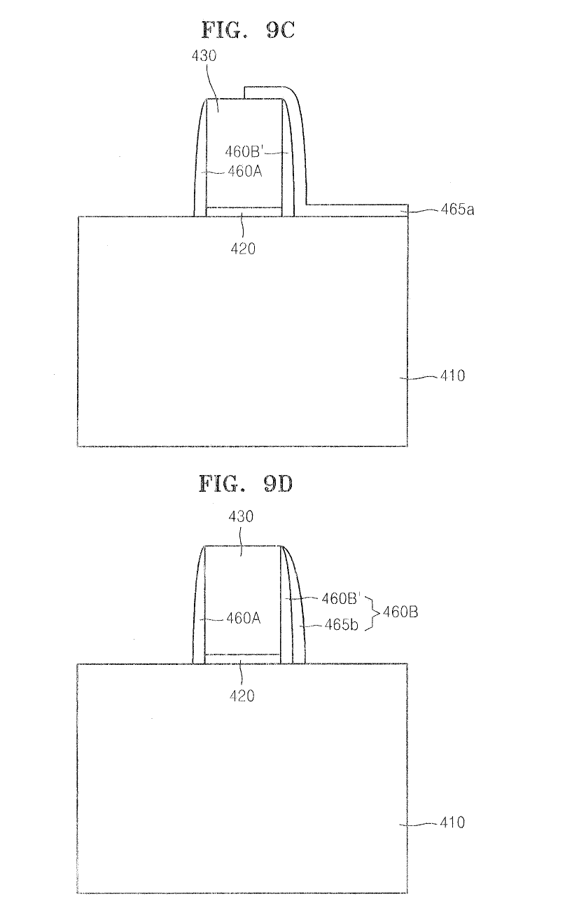

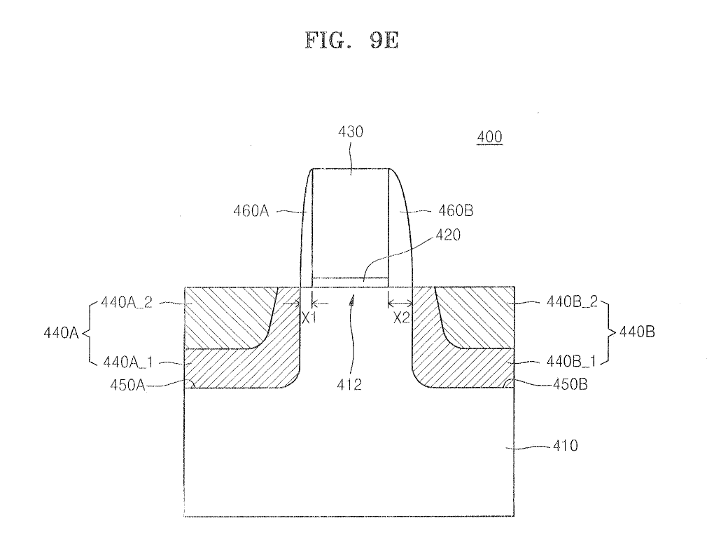

FIGS. 9A to 9E are cross-sectional views illustrating a method of manufacturing the semiconductor device 400 shown in FIG. 5 according to an exemplary embodiment of the present inventive concept.

Referring to FIG. 9A, a gate insulating material layer and a gate structure material layer are formed on a substrate 410 and a mask pattern is formed on the gate structure material layer. Then, the gate insulating material layer and the gate structure material layer are etched by using the mask pattern as an etching mask, thereby forming a gate insulating layer 420 and a gate structure 430. Since the substrate 410, the gate insulating layer 420, and the gate structure 430 are described in detail above, their detailed descriptions are omitted herein.

Then, the etching mask, if any remains, is removed, and then, a first spacer material layer is formed on the entire surfaces of the substrate 410 and the gate structure 430 and anisotropically etched to form first spacers 460A and 460B′.

Referring to FIG. 9B, a second spacer material layer 465 is formed on the entire surfaces of the substrate 410, the gate structure 430, and the first spacers 460A and 460B′, and an etching mask 470 is formed not to cover the first spacer 460A in a source region among the first spacers 460A and 460B′.

The second spacer material layer 465 may include a material having an etch selectivity with respect to the first spacers 460A and 460B′ and the etching mask 470. For example, the first spacers 460A and 460B′ may include a silicon oxide and the second spacer material layer 465 may include a silicon nitride having an etch selectivity with respect to the silicon oxide. The etching mask 470 may include a photoresist material, or a carbon-based material such as an amorphous carbon layer (ACL) or a spin-on hardmask (SOH).

The second spacer material layer 465 may be formed by CVD or ALD. When the photoresist material or SOH is used, the etching mask 470 may be formed by spin coating and patterning the material layer. When ACL is used, the etching mask 470 may be formed by depositing and patterning ACL.

Referring to FIG. 9C, by patterning the second spacer material layer 465 with the etching mask 470 through isotropic etching, a second spacer material layer 465a by which the first spacer 460A in a source region is exposed may be obtained. Then, the etching mask 470 may be removed. When the etching mask 470 includes a carbon-based material, it may be easily removed through a method such as ashing.

Referring to FIG. 9D, a second spacer 465b may be obtained by anisotropically etching the second spacer material layer 465a. The second spacer 465b together with the first spacer 460B′ in the drain region may constitute a spacer 460B in a drain region.

For the anisotropic etching, dry etching methods such as RIE, ICP etching, ECR etching, magnetron plasma etching, capacitively coupled plasma etching, dual-frequency plasma etching, and helicon wave plasma etching may be used.

Referring to FIG. 9E, the substrate 410 is etched by using the first spacers 460A, 460B′, the second spacer 465b, and the gate structure 430 as an etching mask, so that recesses 450A and 450B are obtained. When anisotropic etching is performed to obtain the recesses 450A and 450B, as shown in FIG. 9E, recesses having a box type may be obtained. Unlike that, when isotropic etching is performed to obtain the recesses 450A and 450B, recesses having a sigma shape may be obtained.

The recess 450A in a source region and the recess 450B in a drain region may have substantially the same depth. However, as described above with reference to FIGS. 7A to 7E, the recess 450A in a source region and the recess 450B in a drain region may have different depths.

After the recess 450A in the source region and the recess 450B in the drain region are formed, first layers 440A_1 and 440B_1 and second layers 440A_2 and 440B_2 are formed in the recesses 450A and 450B. Since a method of forming the first layers 440A_1 and 440B_1 and the second layers 440A_2 and 440B_2 is described in detail with reference to FIGS. 7D and 7E, further descriptions thereof are omitted.

FIG. 10 is a circuit diagram of a complementary metal oxide semiconductor (CMOS) inverter 600 according to an exemplary embodiment of the present inventive concept.

The CMOS inverter 600 includes a CMOS transistor 610. The CMOS transistor 610 includes a p-MOS transistor 620 and an n-MOS transistor 630, which are connected between a power terminal Vdd and a ground terminal. The CMOS transistor 610 may include at least one of the semiconductor devices 100, 200, 300, 400, and 500 described with reference to FIGS. 1 to 6.

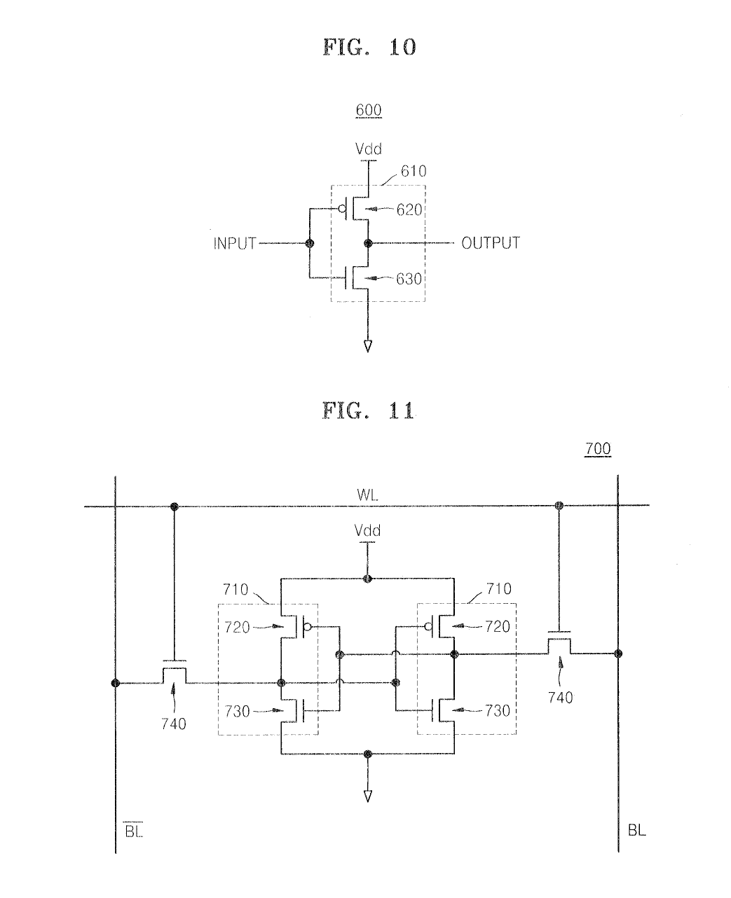

FIG. 11 is a circuit diagram of a CMOS static random access memory (SRAM) device 700 according to an exemplary embodiment of the present inventive concept.

The CMOS SRAM device 700 includes a pair of driving transistors 710. Each of the driving transistors 710 includes a p-MOS transistor 720 and an n-MOS transistor 730, each connected between a power terminal Vdd and a ground terminal The CMOS SRAM device 700 further includes a pair of transfer transistors 740. A source of each of the transfer transistors 740 is cross-connected to a common node of the p-MOS transistor 720 and the n-MOS transistor 730 configuring the driving transistors 710. The power terminal Vdd is connected to the source of the p-MOS transistors 720 and the ground terminal is connected to the source of the n-MOS transistors 730. A word line WL is connected to a gate of each of the transfer transistors 740, and a bit line BL and an inverted bit line are connected to the drain of the transfer transistors 740, respectively.

At least one of the driving transistor 710 and the transfer transistor 740 of the CMOS SRAM device 700 may include at least one of the semiconductor devices 100, 200, 300, 400, and 500 described with reference to FIGS. 1 to 6.

FIG. 12 is a circuit diagram of a CMOS NAND circuit 800 according to an exemplary embodiment of the present inventive concept.

The CMOS NAND circuit 800 includes a pair of CMOS transistors to which different input signals are delivered. One of the CMOS transistors receives INPUT1 at a gate of its p-MOS and n-MOS transistors, while the other CMOS transistor receives INPUT2 at a gate of its p-MOS and n-MOS transistors. Output produced by the CMOS transistors travels via OUTPUT node. Both CMOS transistors are connected to a power terminal Vdd and a ground terminal. At least one transistor configuring the pair of CMOS transistors may include at least one of the semiconductor devices 100, 200, 300, 400, and 500 described with reference to FIGS. 1 to 6.

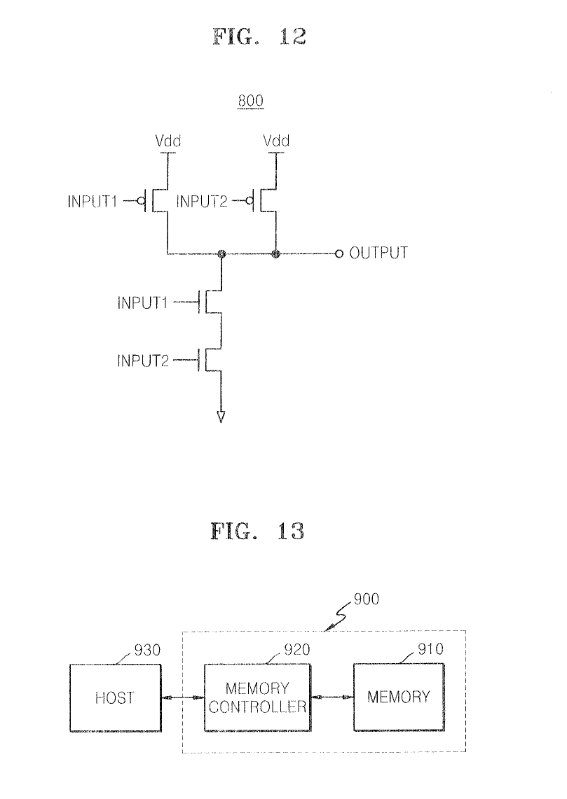

FIG. 13 is a block diagram of an electronic system 900 according to an exemplary embodiment of the present inventive concept.

The electronic system 900 includes a memory 910 and a memory controller 920. The memory controller 920 controls the memory 910 to read data from the memory 910 and/or to write data into the memory 910 in response to the request of a host 930. At least one of the memory 910 and the memory controller 920 may include at least one of the semiconductor devices 100, 200, 300, 400, and 500 described with reference to FIGS. 1 to 6.

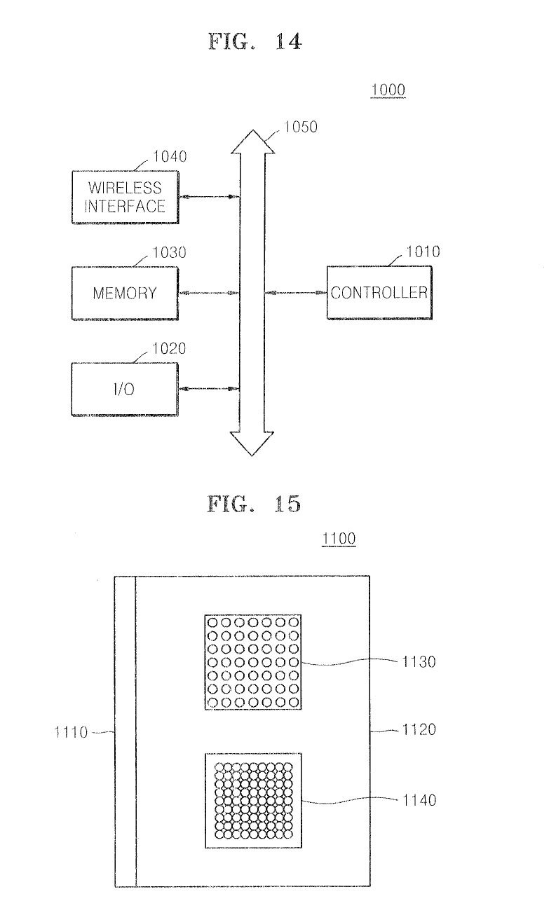

FIG. 14 is a block diagram of an electronic system 1000 according to an exemplary embodiment of the present inventive concept.

The electronic system 1000 may constitute a wireless communication device or a device for transmitting and/or receiving information in a wireless environment. The electronic system 1000 includes a controller 1010, an input/output (I/O) device 1020, a memory 1030, and a wireless interface 1040, which are mutually connected to one another through a bus 1050.

The controller 1010 may include at least one of a microprocessor, a digital signal processor, and processing devices similar thereto. The I/O device 1020 may include at least one of a keypad, a keyboard, and a display. The memory 1030 may be used for storing commands executed by the controller 1010. For example, the memory 1030 may be used for storing user data. The electronic system 1000 may use the wireless interface 1040 to transmit/receive data via a wireless communication network. The wireless interface 1040 may include an antenna and/or a wireless transceiver. In exemplary embodiments of the inventive concept, the electronic system 1000 may be used for an interface protocol of a third generation communication system, for example, code division multiple access (CDMA), global system for mobile communications (GSM), north American digital cellular (NADC), and extended-time division multiple access (E-TDMA), and/or wide band code division multiple access (WCDMA). The electronic system 1000 may include at least one of the semiconductor devices 100, 200, 300, 400, and 500 described with reference to FIGS. 1 to 6.

FIG. 15 is a view of an electronic subsystem 1100 according to an exemplary embodiment of the present inventive concept.

The electronic subsystem 1100 may be a modular memory device. The electronic subsystem 1100 includes an electrical connector 1110 and a printed circuit board 1120. The printed circuit board 1120 may support a memory unit 1130 and a device interface unit 1140. The memory unit 1130 may have a variety of data storage structures. The device interface unit 1140 may be electrically connected to each of the memory unit 1130 and the electrical connector 1110 through the printed circuit board 1120. The device interface unit 1140 may include components necessary for generating voltages, clock frequencies, and protocol logics. The electronic subsystem 1100 may include at least one of the semiconductor devices 100, 200, 300, 400, and 500 described with reference to FIGS. 1 to 6.

While the inventive concept has been particularly shown and described with reference to exemplary embodiments thereof, it will be understood by those of ordinary skill in the art that various changes in form and details may be made therein without departing from the spirit and scope of the inventive concept as defined by the following claims.

What is claimed is:

1. A semiconductor device, comprising:
a substrate having a channel region and first and second recesses disposed on opposite sides of the channel region;
a gate insulating layer disposed on the channel region;
a gate structure disposed on the gate insulating layer; and
a source region disposed in the first recess and a drain region disposed in the second recess,
wherein the source region comprises a first layer disposed on a surface of the first recess and a second layer disposed on the first layer and the drain region comprises a third layer disposed on a surface of the second recess and a fourth layer disposed on the third layer; and
a distance between the gate structure and the second layer of the source region is greater or less than a distance between the gate structure and the fourth layer of the drain region.

2. The semiconductor device according to claim 1, wherein
an upper surface of each of the first and third layers is exposed; and
a width of the third layer exposed in the drain region is greater than a width of the first layer exposed in the source region.

3. The semiconductor device according to claim 2, wherein a depth of the first recess of the source region is greater than a depth of the second recess of the drain region.

4. The semiconductor device according to claim 3, wherein a maximum thickness of the first layer of the source region in a vertical direction is substantially the same as a maximum thickness of the third layer of the drain region in the vertical direction.

5. The semiconductor device according to claim 2, wherein the second recess of the drain region has a box shape and the first recess of the source region has a sigma shape.

6. The semiconductor device according to claim 5, wherein a depth of the second recess of the drain region is less than a depth of the first recess of the source region.

7. The semiconductor device according to claim 2, wherein the first layer and the second layer respectively comprise germanium (Ge) and a germanium concentration of the second layer is higher than a germanium concentration of the first layer.

8. The semiconductor device according to claim 2, wherein the third layer and the fourth layer respectively comprise germanium (Ge) and a germanium concentration of the fourth layer is higher than a germanium concentration of the third layer.

9. The semiconductor device according to claim 1, wherein the semiconductor device is a p-type metal-oxide-semiconductor (MOS) device.

10. The semiconductor device according to claim 1, further comprising:
first and second spacers disposed on lateral side walls of the gate structure,
wherein a thickness of a lower end of the second spacer in a lateral direction between the gate structure and the drain region is greater than a thickness of a lower end of the first spacer in a lateral direction between the gate structure and the source region.

11. The semiconductor device according to claim 10, wherein at least one of the spacers and a corresponding recess side wall are self-aligned.

12. The semiconductor device according to claim 10, wherein an upper end of the first spacer between the gate structure and the source region is at substantially the same level as an upper surface of the gate structure.

13. A semiconductor device, comprising:
a substrate having a channel region and a source region and a drain region disposed on opposite sides of the channel region;
a gate insulating layer disposed on the channel region; and
a gate structure disposed on the gate insulating layer,
wherein the source region and the drain region each comprise germanium (Ge) and each of the source region and the drain region comprises a first layer and a second layer whose germanium concentration is higher than a germanium concentration of the first layer; and
a distance between the gate structure and the second layer of the drain region is greater than a distance between the gate structure and the second layer of the source region.

14. The semiconductor device according to claim 13, wherein a lower surface of the first layer of the source region is lower than a lower surface of the first layer of the drain region.

15. The semiconductor device according to claim 13, further comprising:
first and second spacers disposed on opposite side walls of the gate structure,
wherein a thickness of a lower end of the second spacer in a lateral direction between the gate structure and the drain region is greater than a thickness of a lower end of the first spacer in a lateral direction between the gate structure and the source region.

16. The semiconductor device according to claim 13, wherein the source region and the drain region apply a compressive stress to the channel region.

17. A semiconductor device, comprising:
a source region disposed on a first side of a gate structure, the source region including a first layer and a second layer;
a drain region disposed on a second side of the gate structure, the drain region including a third layer and a fourth layer;
the first layer of the source region is exposed between the gate structure and the second layer of the source region; and
the third layer of the drain region is exposed between the gate structure and the fourth layer of the drain region,
wherein the third layer is exposed more than the first layer.

18. The semiconductor device of claim 17, wherein the source region is disposed in a first recess in a substrate and the drain region is disposed in a second recess in the substrate, wherein a depth of the first recess is greater than a depth of the second recess.

19. The semiconductor device of claim 17, further comprising a first spacer disposed on a first sidewall of the gate structure on the first side of the gate structure and a second spacer disposed on a second sidewall of the gate structure on the second side of the gate structure, wherein the second spacer extends farther from the second sidewall than the first spacer extends from the first sidewall.

20. The semiconductor device of claim 17, wherein the first recess has a sigma shape and the second recess has a box shape.
